(19) United States
(12) Patent Application Publication
(10) Pub. No.: US 2014/0236515 A1
(43) Pub. Date: Aug. 21, 2014

(54) CLOUD-BASED ARCHITECTURE FOR ANALYSIS AND PREDICTION OF INTEGRATED TOOL-RELATED AND MATERIAL-RELATED DATA AND METHODS THEREFOR

(71) Applicants: Tom Thuy Ho, San Carlos, CA (US); Weidong Wang, Union City, CA (US)

(72) Inventors: Tom Thuy Ho, San Carlos, CA (US); Weidong Wang, Union City, CA (US)

(21) Appl. No.: 14/133,499

(22) Filed: Dec. 18, 2013

Related U.S. Application Data
(63) Continuation-in-part of application No. 13/192,387, filed on Jul. 27, 2011.

(51) Int. Cl. H01L 21/66

(52) U.S. Cl. CPC H01L 22/34
USPC 702/84

(57) ABSTRACT

Cloud-based integrated yield/equipment data processing system for collecting and analyzing integrated tool-related data (cause data) and material-related data (effect data) pertaining to at least one material processing tool and at least one material is disclosed. In an embodiment, the tool-related data is correlated with the material-related data and the correlated tool-related data and material-related data is employed by logic to perform, using a cloud computing approach, at least one of root-cause analysis, prediction model building and tool control/optimization.

### PRIORITY CLAIM

This application is a continuation-in-part and claims priority under 35 U.S.C. §120 to a commonly assigned patent application entitled “Architecture for Analysis and Prediction of Integrated Tool-Related and Material-Related Data and Methods Therefor,” by Ho et al.. Attorney Docket Number BIST-P001. application Ser. No. 13/192,387 filed on Jul. 27, 2011, all of which are incorporated herein by reference.

### BACKGROUND OF THE INVENTION

Equipment Engineering System (EES) systems have long been employed to record tool-related data (e.g., pressure, temperature, RF power, process step ID, etc.) in a typical semiconductor processing equipment. To facilitate discussion, FIG. 1A shows a prior art Equipment Engineering System (EES) system 102, which focuses on the semiconductor processing tools (e.g., semiconductor processing systems and chambers) and collects data from tools 104-110. Tools 104-110 may represent etchers, chemical mechanical polishers, deposition machines, etc. The data collected by EES system 102 may represent process parameters such as process temperature, process pressure, gas flow, power consumption, process event data (start, end, step number, wafer movement data, etc.), and the like. EES system 102 may then process the data collected to generate alarm 122 (based on high/low limits, for example), to generate control command 120 (e.g., to start or stop the tool), and to produce analysis results (e.g., charts, tables, and the like).

Yield Management System (YMS) systems have also long been employed to record material-related data (e.g., post-process critical dimension measurements, etch depth measurements, electrical parameter measurements, etc.) on post-processing wafers. FIG. 1B shows a prior art Yield Management System (YMS) 152, which focuses on the wafers and collects data from wafers 154-160. The data collected by YMS system 152 from the wafers may include metrology data (thickness, critical dimensions, number of defects on wafers), electrical measurements that measure electrical behavior of devices, yield data, and the like. The data may be collected at the conclusion of a process step or when wafer processing is completed for a given wafer or a batch of wafers, for example. YMS system 152 may then process the data collected to generate analysis results, which may be presented as chart 160 or result table 162, for example.

Since YMS 152 focuses on yield-related data e.g., measurement data from the wafers. YMS 152 is capable of ascertaining, from the wafers analyzed, which tool may cause a yield problem. For example, YMS 152 may be able to ascertain from the metrology data and the electrical parameter measurements that tool #2 has been producing wafers with poor yield. However, since VMS 152 does not focus on or collect significant and detailed tool-related data, it is not possible for YMS system 152 to ascertain the conditions and/or settings (e.g., the specific chamber pressure during a given etch step) on the tool that may cause the yield-related problem. Further, as an example, lacking access to the data regarding the tool conditions/settings, it is not possible for YMS 152 to perform analysis to ascertain the common tool conditions/settings (e.g., chamber pressure or bias power setting) that exist when the poor yield processing occurs on one or more hatches of wafers. Conversely, since EES 102 focuses on tool-related data, EES 102 may know about the chamber conditions and settings that exist at any given time but may not be able to ascertain the yield-related results from such conditions or settings.

In the prior art, a process engineer, upon seeing the poor process results generated by YMS 152, typically needs to access other tools (such as EES 102) to obtain tool-related data. By painstakingly correlating YMS data pertaining to low wafer yield to data obtained from tools (e.g., EES data), the engineer may, with sufficient experience and skills, be able to ascertain the parameter(s) and/or sub-step of the process(es) that cause the low wafer yield.

However, this approach requires highly skilled experts performing painstaking, time-consuming data correlating between the YMS data from the YMS system and the EES data from the EES system and painstaking, time-consuming analysis (e.g., weeks or months in some cases) and even if such experts can successfully correlate manually the two (or more) independent systems and detect the root cause of the yield related problem, the prior art process is still time consuming and incapable of being leveraged for timely automatic analysis of cause/effect data to facilitate problem detection and/or alarm generation, and/or tool control and/or prediction with a high degree of data granularity.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1A shows a prior art Equipment Engineering System (EES) system, which focuses on the semiconductor processing tools

FIG. 1B shows a prior art Yield Management System (YMS), which focuses on the wafers and collects data from wafers.

FIG. 2 shows, in accordance with an embodiment of the invention, a YiEES (Yield Intelligence Equipment Engineering System), which collects tool-related data from THE tools as well as wafer-related data from wafers and implements an integrated analysis and prediction platform based on the integrated data.

FIG. 3 shows, in accordance with an embodiment of the invention, a more detailed view of a YiEES system.

FIG. 4 shows the implementation of an example online control/optimization module that is analogous to the plug-and-play modules discussed in connection with the online control/analysis layer of FIG. 3.

FIG. 5 illustrates, in accordance with an embodiment of the invention, the improved analysis technique with pre-filtering via classification/clustering and/or using different analysis methodologies and/or different statistical techniques.

FIG. shows, in accordance With an embodiment of the invention a cloud-based YiEES (Yield Intelligence Equipment Engineering System)

FIG. 7 show, in accordance with an embodiment of the invention, a more detailed view of a cloud-based YiEES system.

FIG. 8 shows an example cloud-based statistical process control that has been implemented as a service using the cloud-based approach.

FIG. 9 shows the implementation of an example cloud-based online control/optimization module that is analogous to the plug-and-play modules discussed in connection with cloud-based online control/analysis layer of FIG. 7.

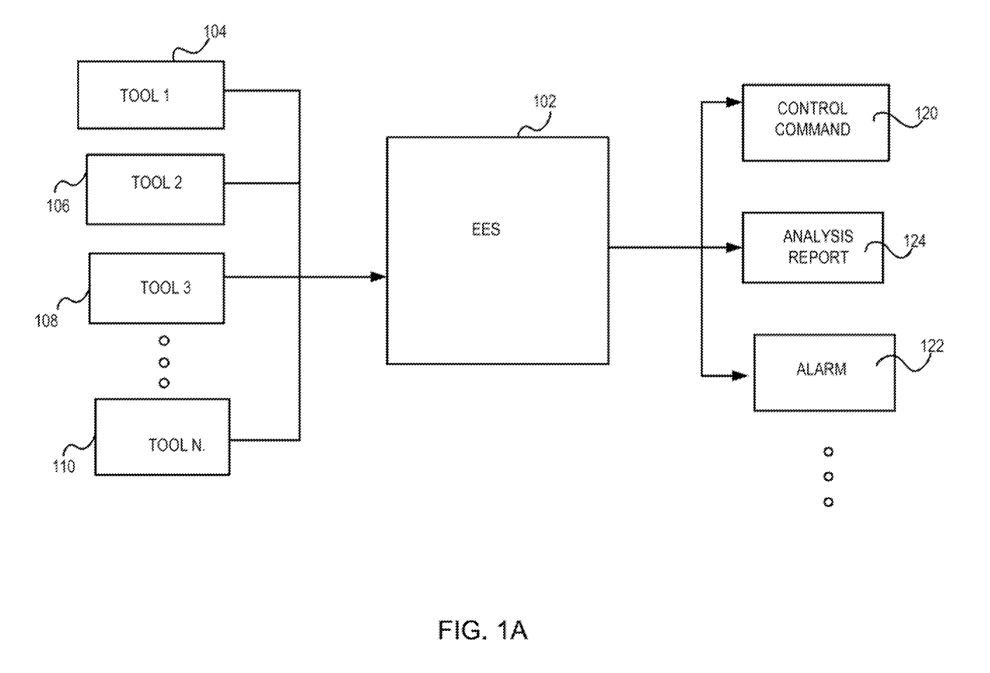

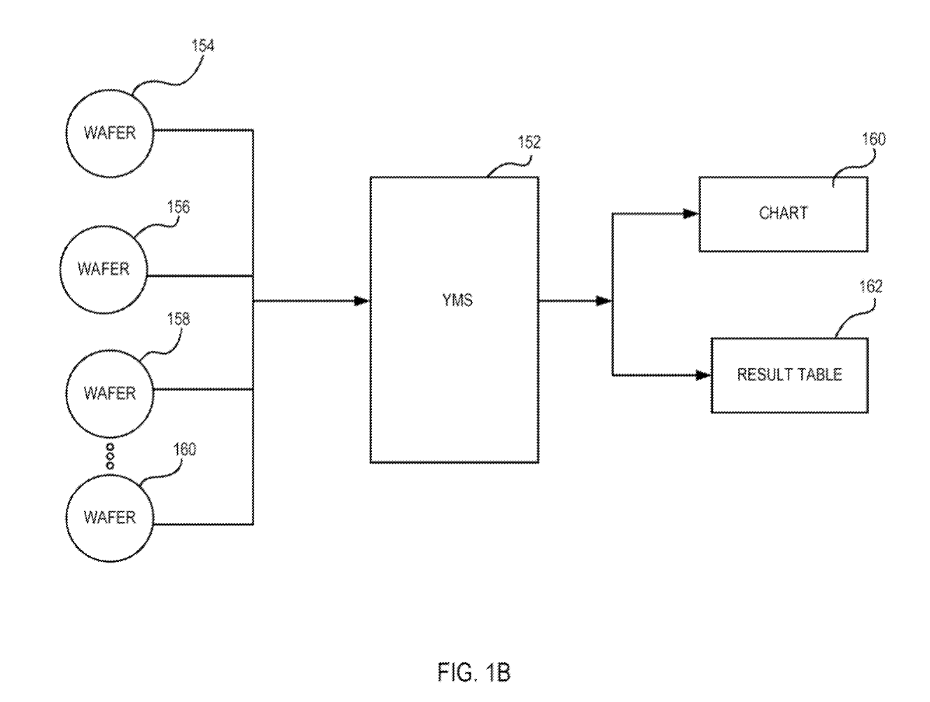

### DETAILED DESCRIPTION OF EMBODIMENTS

The present invention will now be described in detail with reference to a few embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

Various embodiments are described herein below, including methods and techniques. It should be kept in mind that the invention might also cover articles of manufacture that includes a computer readable medium on which computer-readable instructions for carrying out embodiments of the inventive technique are stored. The computer readable medium may include, for example, semiconductor, magnetic, opto-magnetic, optical, or other forms of computer readable medium for storing computer readable code. Further, the invention may also cover apparatuses for practicing embodiments of the invention. Such apparatus may include circuits, dedicated and/or programmable, to carry out tasks pertaining to embodiments of the invention. Examples of such apparatus include a general-purpose computer and/or a dedicated computing device when appropriately programmed and may include a combination of a computer/computing device and dedicated/programmable circuits adapted for the various tasks pertaining to embodiments of the invention.

Embodiments of the invention relate to systems for integrating both cause data (tool related or process-related data) and effect data (material-related or material-related data) on a single platform. In one or more embodiments, an integrated yield/equipment data processing system for collecting and analyzing integrated tool-related data and material-related data pertaining to at least one wafer processing tool and at least one wafer is disclosed. By integrating cause-and-effect data in a single platform, the data necessary for automated problem detection (e.g., automated root cause analysis) and prediction is readily available and correlated, which shortens the cycle time to detection and facilitates efficient and timely automated tool management and control.

As the term is employed herein, the synonymous term “automatic”, “automatically” or “automated” (e.g., automated root cause analysis, automated problem detection, automated model building, etc.) denotes, in one or more embodiments, that the action (e.g., analysis, detection, optimization, model building, etc.) occur automatically without human intervention as tool-related and material-related data are received, correlated, and analyzed by logic (software and/or hardware). In one or more embodiments, prior human input (in the form of domain knowledge, expert knowledge, rules, etc.) may be pre-stored and employed in the automated action, but the action that results (e.g., analysis, detection, optimization, model building, etc.) does not need to wait for human intervention to occur after the relevant tool-related and material-related data are received. In one or more embodiments, minor human intervention (such as issuing the start command) may be involved and is also considered part of the automated action but on the whole, all the tool-related and material-related data as well as models, rules, algorithms, logic, etc. to execute the action (e.g., analysis, detection, optimization, model building, etc.) are available and the action does not require substantive input by the human operator to occur.

As the term is employed herein, a knowledge base is a storage area designed specifically for storing, classifying, indexing, updating, and searching domain knowledge and case study results (or historical results). It may contain tool and process profiles, models for prediction, analysis control and optimization. The content in the knowledge base can be input and updated manually or automatically using the YiEES system. It is used as prior knowledge by YiEES system for model building, analysis, tool and process control and optimization.

For example, one or more embodiments of the invention integrate both cause and effect data on a single platform to facilitate automatic analysis using computer-implemented algorithms that automatically detect material-related problems and pin-point the tool-related data (such as a specific pressure reading on a specific tool) that causes such material-related problems and/or build prediction models for better process control identify optimal process condition, provide prediction for timely machine maintenance, etc. Once the root cause is determined/or an model is built and traced to a specific tool and/or step in the process, automated tool control may be initiated to correct the problem or set the process to its optimal condition, for example.

In this manner, the time-consuming aspect of manual data correlation and analysis of the prior art is substantially eliminated. Further, by removing the need for human data correlation and analysis, human-related errors can be substantially reduced. Root cause analysis may now be substantially automated, which reduces error and improves speed.

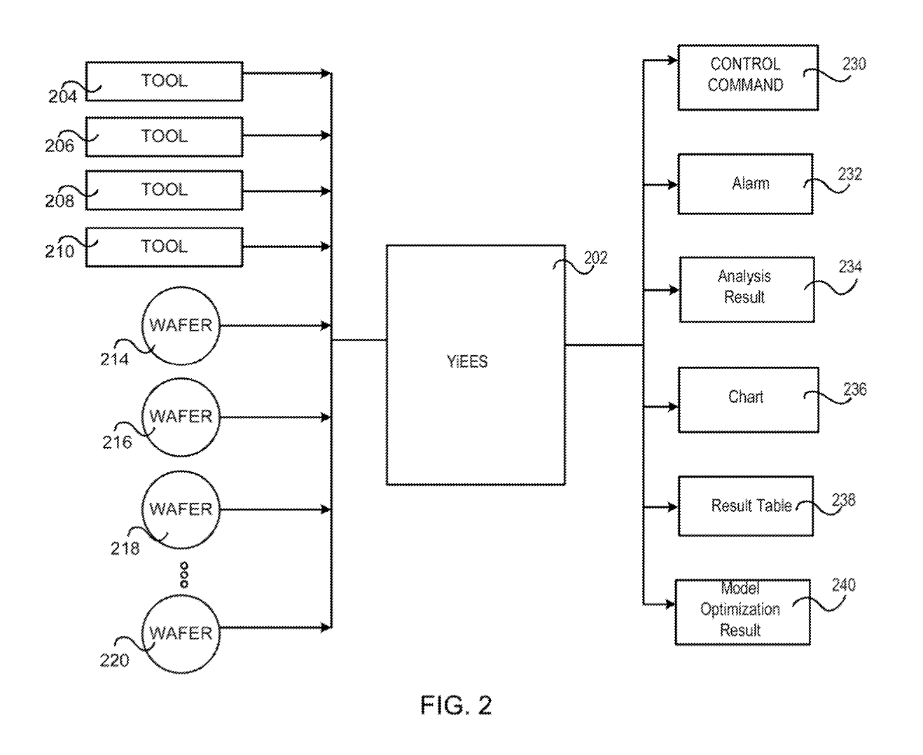

The features and advantages of embodiments of the invention may be better understood with reference to the figures and discussions that follow. FIG. 2 shows, in accordance with an embodiment of the invention, a YiEES (Yield Intelligence Equipment Engineering System) 202, representing an implementation of the aforementioned integrated yield/equipment data processing system, which collects tool-related data from tools 204-210 as well as wafer-related data from wafers 214-220. The tool and wafer data is then input into YiEES 202, which performs automated analysis or model optimization based on both the effect data (e.g., wafer-related measurements made on the wafers) and the cause data (e.g., tool parameters or process step data). The result of the automated analysis and/or model optimization may then be employed for automated tool command and control 230, alarm generation 232, analysis result generation 234, model optimization result 240, chart generation 236, and/or result table generation 238.

The material-related data from tools 214-220 may be collected using an appropriate I/O module or I/O modules and may include, for example, wafer ID or material ID, wafer history data or material history data, which contains the date/time information, the process step ID, the tool ID, the processing, recipe ID, and any material-related quality measurements such as any physical measurements, for example film thickness, film resistivity, critical dimension, defect data, and any electrical measurements, for example transistor threshold voltage, transistor saturation current (IDSAT), or any equivalent material-related quality measurements. The tool-related data from tools 204-210 may be collected using an appropriate I/O module or I/O) modules and may include, for example, the date/time information, the tool ID, the processing recipe ID, subsystems and tool component historical data, and any other process-related measurements, for example pressure, temperature, gas flows

In one or more embodiments, the date/time, tool ID and optionally recipe ID, may be employed as common attributes or correlation keys to align or correlate, using appropriate logic (which may be implemented via dedicated logic or as software executed in a programmable logic/processor for example) the tool-related, data with the material-related data (for example, tool-related parameter values with metrology measurement values on specific materials (i.e., wafers), thereby permitting a computer-implemented algorithm to correctly correlate and perform the automated analysis on the combined material-related data and tool-related data.

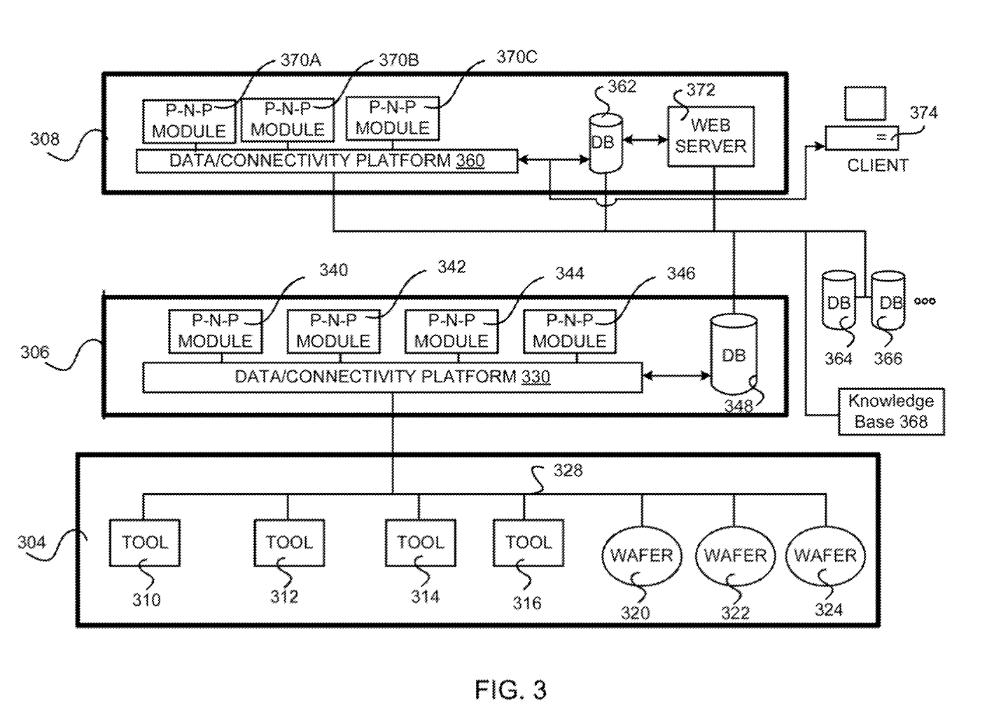

FIG. 3 shows, in accordance with an embodiment of the invention, a more detailed view of a YiEES system. With respect to FIG. 3, the YiEES system includes 3 conceptual layers: data layer 304, online control/analysis layer 306, and offline analysis layer 308. Data layer 304 represents layer wherein the tools (310-316) and/or waters (320-324) conceptually reside and from which tool-related and material-related data may be obtained via appropriate I/O modules. In general terms, the tool-related data may be thought of as cause data for the automated analysis, and material-related data may be thought of as effect data for the automated analysis. As can be seen in FIG. 3, both the cause and effect data are present in a single platform, collected and sent to online/analysis layer 306 via bus 328.

Online control/analysis layer 306 represents the layer that contains the plug-and-play modules for performing automated control, optimization, analysis, and/or prediction based on the integrated tool-related and material-related data collected from data layer 304. To facilitate plug-and-play modules for online control/analysis, a data/connectivity platform 330 serves to interface with bus 328 to obtain tool-related and material-related data from data layer 304 as well as to present a standard interface to communicate with the plug-and-play modules. For example, data/connectivity platform 330 may implement APIs (application programming interfaces) with pre-defined connectivity and communication options for the plug-and-play modules.

Plug-and-play modules 340, 342, 344, 345 represent 4 plug-and-play modules to, for example, perform the automated control (SPC, MPC, APC), tool profiling, process profiling, tool optimization, processing optimization, modeling building, dynamic model update and modification, analysis, and/or prediction using the integrated tool-related and material-related data collected from data layer 304. The plug-and-play modules may be implemented via dedicated logic or as software executed in a programmable logic/processor, for example. Each of plug-and-play modules 340, 342, 344, 345 may be configured as needed depending on the specifics of a process, the needs of a particular customer, etc. Sharing the same platform allow each module to feed and receive useful information from others.

For example, if the YiEES system, for example the offline analysis part (to be discussed later herein), found a strong correlation between a specific tool-related parameter (such as etch time) with as material-related parameter of interest (e.g., leakage current of transistors), this knowledge is saved in the knowledge base 368 as part of the tool profile and/or used to create or update existing models related to this tool/or process in process control, prediction, and/or process optimization. A plug-and-play module 340 that is coupled with data/connectivity layer 330 may monitor etch time values (e.g., with high/low limit) and use the result of that monitoring to control the tool and/or optimize the tool and/or process in order to ensure the process is controlled/optimized to satisfy a particular leakage current specification. The new knowledge can also be used by existing module for new model creation or existing model updates. This is an example of a plug-and-play tool that can be configured and updated quickly by the tool user and plugged into data/connectivity platform 330 to receive integrated tool-related and material-related data (e.g., both cause and effect data) and to provide additional control/optimization capability to satisfy a customer-specific material-related parameter of interest.

As another example, if the YiEES system, for example the off-line analysis part (to be discussed later herein), found a strong correlation between a group of specific tool-related parameters (such as etch time and chamber pressure and RF power to the electrodes) with as material-related parameter of interest (e.g., critical dimension of a via), this knowledge is saved in the knowledge base as part of the tool profile and/or used to create or update existing models related to this tool/or process in process control, prediction, and/or process optimization. A plug-and-play module 342 that is coupled with data/connectivity layer 330 may monitor values associated with this group of specific tool-related parameters (which may be conceptualized as a virtual parameter that is a composite of individual tool-related parameters) and use the result of that monitoring to control the tool and/or optimize the tool and/or process in order to ensure the process is controlled/optimized to satisfy a particular via CD (critical dimension) specification. The new knowledge can also be used by existing module for new model creation or existing model optimization. This is an example of another plug-and-play tool that can be configured and updated quickly by the tool user and plugged into data/connectivity platform 330 to receive integrated tool-related and material-related data (e.g., both cause and effect data) and to provide additional control/optimization capability to satisfy a customer-specific material-related parameter of interest or a group of material-related parameters of interest.

As another example, if the YiEES system, for example the off-tine analysis part (to be discussed later herein), found a strong correlation between specific tool-related (e.g. temperature) parameter and/or material-related (e.g., leakage current) parameter with yield, this knowledge is saved in the knowledge base as part of the tool profile and/or used to create or update existing models related to this tool/or process in process control, prediction, and/or process optimization. Plug-and-play module 344 or plug-and-play module 346 that is coupled with data/connectivity layer 330 in order to monitor these specific tool-related parameter (e.g., temperature) and material-related parameter leakage current) may predict the yield with high data granularity. The new knowledge can also be used by existing module for new model creation or existing model optimization. Each of modules 344 or 346 is an example of as plug-and-play tool that can be configured and updated quickly by the tool user and plugged into data/connectivity platform 330 to receive integrated, tool-related and material-related data (e.g., both cause and effect data) and to provide analysis and/or prediction capability to satisfy to customer-specific yield requirement.

Online integrated tool-related and material-related database 348 represents a data store that stores at least sufficient data to facilitate the online control/analysis needs of modules 340-346. Since database 348 conceptually represents the data store serving the online control/analysis needs, archive tool-related and material-related data from past processes may be optionally stored in database 348 (but not required in database 348 in one or more embodiments).

Offline analysis layer 308 represents the layer that facilitates off-line data extraction, analysis, viewing and/or configuration by the user. In contrast to online control/analysis layer 306, offline analysis layer 308 relies more heavily on archival data as well as analysis result data from online control/analysis layer 306 (instead of or in addition to the data currently collected from tools 310-316 and wafers 320-324) and/or knowledge base and facilitates interactive user analysis/viewing/configuration.

A data/connectivity platform 360 serves to interface with online control/analysis layer 306 to obtain the data currently collected from tools 310-316 and wafers 320-324, from the analysis result data from the plug-and-play modules of online control/analysis layer 306, from the data stored in database 348, from a knowledge base from the archival database 362 (which stores tool-related and material-related data), and/or from the legacy databases 364 and 366 (which may represent, for example, third-party or customer databases that may have tool-related or material-related or analysis results that may be of interest to the off-line analysis).

Data/connectivity platform 360 also presents a standard interface to communicate with the plug-and-play offline modules. For example, data/connectivity platform 360 may implement APIs (application programming interfaces) with pre-defined connectivity and communication options for the offline plug-and-play extraction module or offline plug-and-play configuration module or offline plug-and-play analysis module or offline plug-and-play viewing module. The off-line plug-and-play modules may be implemented via dedicated logic or as software executed in a programmable logic/processor, for example. These offline extraction, analysis, configuration and/or viewing modules may be quickly configured as needed by the customer and plugged into data/connectivity platform 360 to receive current and/or archival integrated tool-related and material-related data (e.g., both cause and effect data) as well as current and/or archival online analysis results and/or data from third party databases in order to service a specific extraction, analysis, configuration and/or viewing need.

Interaction facility (comprising items 370a, 370b, and 370c) conceptually implements the aforementioned offline plug-and-play modules and may be accessed by any number of user-interface devices, including for example smart phones, tablets, dedicated control devices, laptop computers, desktop computers, etc. In terms of viewing, different industries may have different preferences for different viewing methodologies (e.g., pie chart versus timeline versus spreadsheets). A web server 372 and a client 374 are shown to conceptually illustrate that offline extraction, analysis, configuration and/or viewing activities may be performed via the internet, if desired.

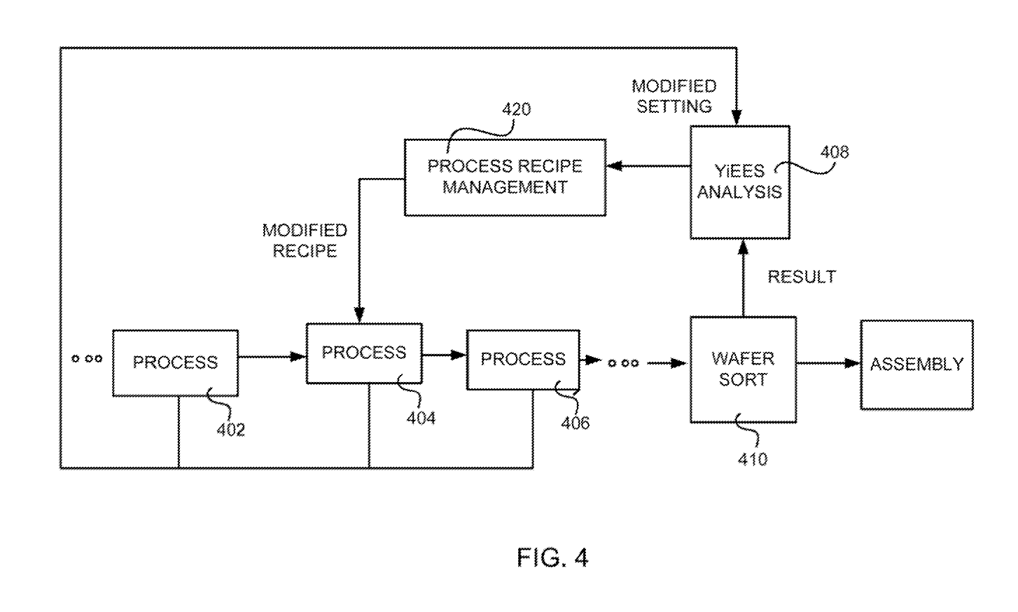

FIG. 4 shows the implementation of an example online control/optimization module that is analogous to the plug-and-play modules discussed in connection with online control/analysis layer 306 of FIG. 3. In FIG. 4, the tool-related data from processes 402, 404, and 406 (which may represent respectively metal etch, polysilicon etch, and CMP, for example) may be collected and inputted into a control/optimization module 408. Once processing is done, wafer sort process 410 may perform electrical parameter measurements, device yield measurements, and/or other measurements and input the material-related data into control/optimization module 408.

Control/optimization module 408, which represents as plug-and-play module, may automatically analyze the tool-related data and the material-related data and determine that there is a correlation between chamber pressure during the polysilicon etch step (a tool-related data parameter) and the leakage current of a gate to material-related data parameter). This analysis result may be employed to modify a recipe setting, which is sent to process recipe management block 420 to create a modified recipe to perform tool control or to optimize tool control for tool 404. Note that the presence of highly granular tool-related data and material-related data permit root cause analysis that narrows down to one or more specific parameters in a specific tool, which facilitates highly accurate recipe modification. Accordingly, the availability of both tool-related data and material-related data and the ease of configuring/implementing a plug-and-play module to perform the analysis on the integrated tool-related data and material-related data greatly simplify the automated analysis and control task. In addition, based on the above analysis, a prediction model can be built or optimized and its results can be passed to other plug and play modules (for example 406) as inputs. This is also an example of feed-forward and feed-backward capability of the plug and play module in the system.

Automated analysis of effect (e.g., yield result based on integrated tool-related and material-related data) and/or prediction (e.g., predicted yield result based on integrated tool-related and material-related data) may be improved using a knowledge base. In one or more embodiments, human experts may input root-cause analysis or prediction knowledge into a knowledge base to facilitate analysis and/or prediction. The human expert may, for example, indicate a relationship between saturation current measurements for a transistor gate and polysilicon critical dimension (C/D).

Previously obtained root-cause analysis (which pinpoints tool-related parameters correlating to yield-related problems) and previously obtained prediction models from the YiEES system (such as from one or more of plug-and-play modules 340-346 of online control/analysis layer 306 of FIG. 3 or one or more of plug-and-play modules of online analysis layer 308) may also be input into the knowledge base. For example, prior analysis may correlate a particular etch pattern on the wafer with a particular pressure setting on a particular tool. This correlation may also be stored into the knowledge base.

The root-cause analysis and/or prediction knowledge from the human expert and/or from prior analysis/prediction module outputs may then be applied against the integrated tool-related data and material-related data to perform root cause analysis or to build new prediction models. The combination of a knowledge base, tool-related data, and material-related data in a single platform renders the automated analysis more accurate and less time-consuming.

In one or more embodiments, multiple potential root causes or prediction models may ne automatically provided by the knowledge base, along with a ranking of probability, in order to give the tool operator multiple options to investigate. Furthermore, the root-cause analysis and/or prediction models obtained using the assistance of the knowledge base may be stored back into the knowledge base to improve future root-cause analysis and/or prediction. To ensure the accuracy of the generated root-cause analysis or prediction models, cross validation using independent data may be performed periodically if desired.

Expert or domain knowledge may also be employed to automatically filter the analysis result candidates or influence the ranking (via changing the weight assigned to the individual results, for example) of the analysis result candidates. For example, the set of candidate analysis results (obtained with statistical method alone or with or without knowledge base assistance) may be automatically filtered by expert or domain knowledge to de-emphasize certain analysis result, or emphasize certain analysis result, or eliminate certain analysis result, in order to influence the ranking of the analysis result candidates.

As an example, the expert may input, as a rule into the analysis engine, that yield loss around the edge is likely associated with etch problems and more specifically with high bias power during the main etch step. Accordingly, the set of analysis result candidates that may have been obtained using a purely statistical approach or a combination of a statistical approach and other knowledge base rules may be influenced such that those candidates associated with etch problems and more specifically those analysis results associated with high bias power during main etch step would be emphasized (and other candidates de-emphasized). Note that this type of root cause analysis granularity is possible only with the provision of integrated tool-related data and material-related data in a single platform, in accordance with one or more embodiments of the invention.

Analysis may, alternatively or additionally, be made more efficient/accurate by first performing automated clustering/classification of wafers, and then applying different automated analyses to different groups of wafers. With the availability of material-related data, it is possible to cluster or classify the processed wafers into smaller subsets for more efficient/accurate analysis.

For example, the processed wafers may be grouped according the processed patterns (e.g., over-etching along the top half, over-etching along the bottom half, etc.) or any tool-related parameter (e.g., chamber pressure) or any material-related parameter (e.g., a particular critical dimension range of values) or any combination thereof. Note that this type of classification/clustering is possible because both highly granular tool-related and material-related data are available and aligned on a single platform. Generically speaking, clustering/classification aims to group subsets of the materials into “single cause” groups or “single dominant cause” groups to improve accuracy in, for example, root-cause analysis. For example, when a subset of the materials (e.g., wafers) are grouped into a group that reflects a similar process result or a set of similar process results, it is likely to be easier to pinpoint the root cause for the similar process result(s) for that subset than if the wafers are arbitrarily grouped into arbitrary subsets/groups without regard for process result similarities or not grouped at all.

Classification refers to applying predefined criteria or predefined libraries to the current data set to sort the wafer set into predefined “buckets”. Clustering refers to applying statistical analysis to look for common attributes and creating sub-sets of wafers based on these common attributes/parameters.

In accordance with one or more embodiments, different types of analysis may then be applied to each sub-set of wafers after classification/clustering. By way of example, if a sub-set of wafers has been automatically grouped based on a specific range of critical dimension and it is known that critical dimension is not influenced by process gas flow volume, for example, considerable time/effort can be saved by not having to analyze that subset of wafers for correlation with process gas flow.

However, that subset of wafers may be analyzed in as more focused and/or detailed manner using a particular analysis methodology tailored toward detecting problems with critical dimensions. Examples of different analysis methodologies include equipment analysis, chamber analysis, recipe analysis, material analysis, etc.

In accordance with one or more embodiments, different statistical methods may be applied to different subsets of wafers after clustering/classification (depending on, for example, how/why these wafers are classified/clustered and/or which analysis methodology is employed). For example, a specific statistical method may be employed to automatically analyze wafers grouped for equipment analysis while another specific statistical method may be employed to analyzed wafers grouped for recipe analysis. This is unlike the prior art wherein a single statistical method tends to be employed for all root-cause analyses for the whole batch of wafers. Since both tool-related and material related data are available, automated analysis may pinpoint the root-cause to a specific tool parameter or a specific combination of tool parameters. This type of data granularity is not possible with prior art systems that only have tool-related data or material-related data.

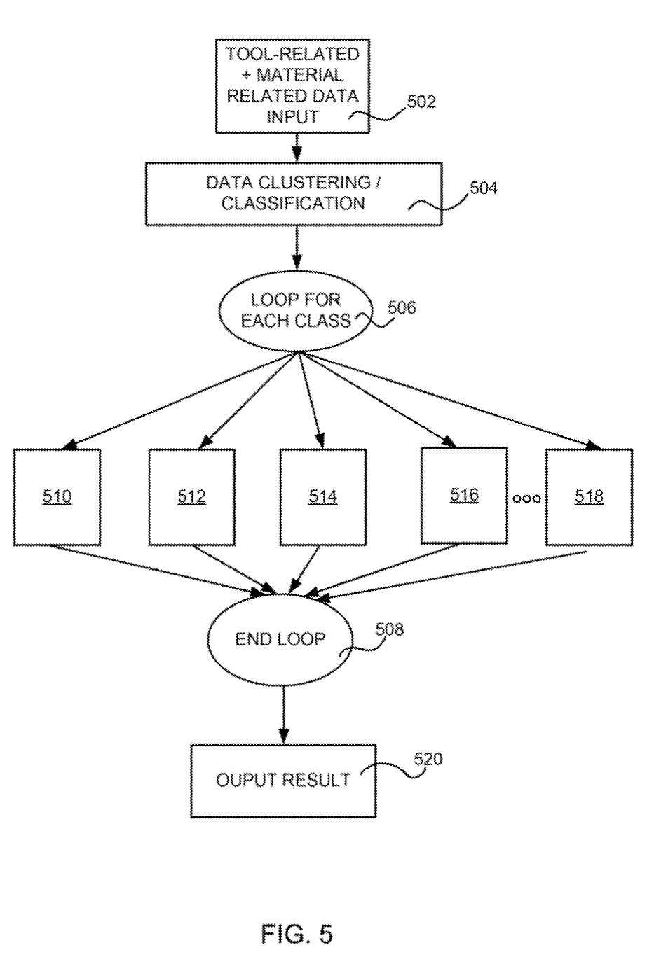

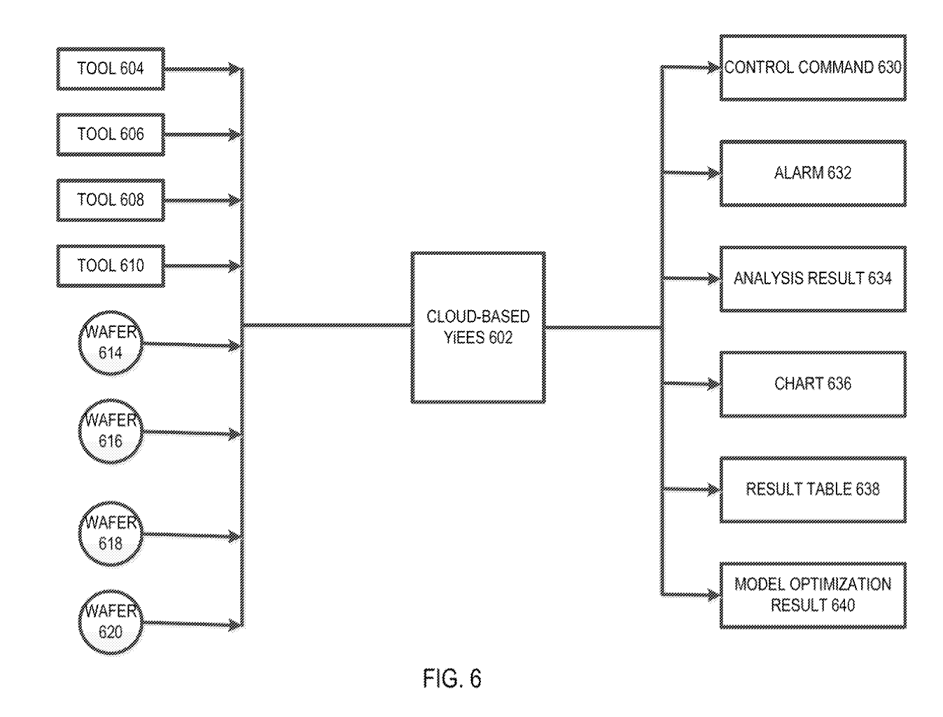

FIG. 5 illustrates, in accordance with an embodiment of the invention, the improved analysis technique with pre-filtering via classification/clustering and/or using different analysis methodologies and/or different statistical techniques. In block 502, the integrated tool-related data and material-related data are inputted. In block 504, data clustering and/or data classification may be performed on the wafers to create subsets of wafers as discussed earlier. These subsets of wafers are analyzed using suitable analysis methodologies (blocs 510, 512, 514, 516, 518) until all subsets are analyzed (iterative blocks 506 and 508. As discussed, a specific statistical method may be employed to analyze wafers grouped for equipment analysis (510) while another specific statistical method may be employed to analyzed wafers grouped for recipe analysis (516), for example. The analysis results are then outputted in block 520.

As can be appreciated from the foregoing, the integration and data alignment of both cause and effect data (e.g., tool-related data and material-related data) in the same platform simplify the task of automatically correlating data from traditional EES system and YMS system, as well as facilitate time-efficient automated analysis. The use of automated data alignment and automated analysis also substantially eliminates human-related errors in the data correlation and automated data analysis tasks. Since high granularity tool-related data and process-related data are available on a single platform, both automated root cause analysis and automated prediction may be more specific and timely, and it becomes possible to quickly pinpoint a yield-related problem to a specific tool-related parameter (such as chamber pressure in tool #4) or a group of tool-related parameters (such as chamber pressure and bias power in tool #2). Furthermore, the use of knowledge base and/or cross-validation and/or wafer clustering/classification also improves the automated analysis results.

In one or more embodiments of the invention, the YiEES arrangements and techniques discussed in connection with FIGS. 2-5 are implemented using cloud computing technology and techniques. The use of cloud computing enables a semiconductor manufacturer to handle greater volume and variety of data (i.e., different formats) with improved scalability, hardware/software maintenance/management efficiency and lower cost.

Generally speaking, the National Institute of Standards and Technology's definition of cloud computing identifies “five essential characteristics”. First, cloud computing is closely associated with on-demand self-service. A user can unilaterally provision computing capabilities, such as server time and network storage, as needed automatically without requiring human interaction with each service provider. Second, cloud computing involves broad network access. Capabilities are available over the network and accessed through standard mechanisms that promote use by heterogeneous thin or thick client platforms e.g., mobile phones, tablets, laptops, and workstations). Third, cloud computing promotes resource pooling. The provider's computing resources are pooled to serve multiple users using a multi-tenant model, with different physical and virtual resources dynamically assigned and reassigned according to consumer demand. Fourth, cloud computing results in rapid elasticity. Capabilities can be elastically provisioned and released, in some cases automatically, to scale rapidly outward and inward commensurate with demand. To the user, the capabilities available for provisioning often appear unlimited and can be appropriated in any quantity at any time. Fifth, cloud computing makes extensive use of measured service. Cloud systems automatically control and optimize resource use by leveraging a metering capability at some level of abstraction appropriate to the type of service (e.g., storage, processing, bandwidth, and active user accounts). Resource usage can be monitored, controlled, and reported, providing transparency for both the provider and consumer of the utilized service.

To further elaborate, cloud computing differs from the traditional client-server model and tends exhibits the following key characteristics. Agility improves with users' ability to re-provision technological infrastructure resources. Application programming interface (API) accessibility to software that enables machines to interact with cloud software in the same way that a traditional user interface (e.g., a computer desktop) facilitates interaction between humans and computers. Cloud computing systems typically use Representational State Transfer (REST)-based APIs, for example. Cost tends to be reduced as infrastructure is typically provided on a flexible basis and does not need to be specifically set aside for one-time or infrequent intensive computing tasks.

Cloud computing also offers device and location independence, thereby enabling users to access systems using a web browser regardless of their location or what device they are using (e.g., PC, mobile phone). As infrastructure may be on-site or off-site (and may even be provided by a third-party) and accessed via the Internet, users can connect from anywhere.

A key enabler of cloud computing is virtualization. Virtualization technology allows servers and storage devices to be shared and utilization be increased. Applications can be easily migrated from one physical server to another.

Another key characteristic of cloud computing is multitenancy, which enables sharing of resources and costs across a large pool of users. Multitenancy allows for 1) centralization of infrastructure in locations with lower costs (such as real estate, electricity, etc.), 2) peak-load capacity increases (users need not engineer their systems for highest possible load-levels), 3) utilization and efficiency improvements for systems that are often only 10-20% utilized.

Reliability is improved when multiple redundant sites are used, which makes well-designed cloud computing suitable for business continuity and disaster recovery. Cloud computing enables scalability and elasticity via dynamic (“on-demand”) provisioning of resources on a fine-grained, self-service basis near real-time, again without users having to engineer their systems for peak loads.

Generally speaking, performance is monitored, and consistent and loosely coupled architectures are constructed using web services as the system interface. Security is improved due to centralization of data, increased security-focused resources. If desired, the cloud computing environment (such as that employed for the YiEES system) could be implemented behind a firewall, essentially insulating the cloud computing environment from the public network and enabling a greater user control over sensitive data and security for stored kernels.

Maintenance of cloud computing applications tends to be easier, because the applications do not need to be installed on each user's computer and can be accessed from different places.

In one or more embodiments, the YiEES (Yield Intelligence Equipment Engineering System) of FIGS. 2-5 is implemented using as cloud computing approach. FIG. 6 shows, in accordance with an embodiment of the invention, a cloud-based YiEES (Yield intelligence Equipment Engineering System) 602, representing an implementation of the aforementioned integrated yield/equipment data processing system implemented using cloud computing.

The cloud-based YiEES system of FIG. 6 collects tool-related data from tools 604-610 as well as wafer-related data from wafers 614-620. The tool and wafer data is then input into cloud-based YiEES 602, which performs automated analysis or model optimization based on both the effect data (e.g., wafer-related measurements made on the wafers) and the cause data (e.g., tool parameters or process step data).

In contrast with the implementation of FIG. 2, the implementation of FIG. 6 employs a cloud computing approach. Cloud computing may employ cloud computing services offered by vendors such as Amazon Web Services (Amazon.com of Seattle, Wash.) or IBM Corporation (Armonk, N.Y.) or other commercially-available cloud-computing vendors. If installed as a private cloud, the cloud computing platform may utilize, in one or more embodiments, the Hadoop® framework (apache.org,), which represents open-source software for enabling reliable, scalable, distributed computing. In brief, the Hadoop® framework allows for the distributed processing of large data sets across clusters of computers using simple programming models. It is designed to scale up from single servers to thousands of machines, each offering local computation and storage. Rather than rely on hardware to deliver high-availability, the Hadoop® software library itself is designed to detect and handle failures at the application layer, so delivering a highly-available service on top of a cluster of computers, each of which may be prone to failures. Among modules offered are 1) Hadoop Common: The common utilities that support the other Hadoop modules; 2) Hadoop Distributed File System (HDFS™): A distributed file system that provides high-throughput access to application data; 3) Hadoop YARN; A framework for job scheduling and cluster resource management; and 4) Hadoop MapReduce: A YARN-based system for parallel processing of large data sets.

Referring back to FIG. 6, the cloud-based YiEES produces automated analysis and/or model optimization, which may then be employed for automated tool command and control 630, alarm generation 632, analysis result generation 634, model optimization result 640, chart generation 636, and/or result table generation 638.

The material-related data from tools 614-620 may be collected using an appropriate module or I/O modules and may include, for example, wafer ID or material ID, wafer history data or material history data, which contains the date/time information, the process step ID, the tool ID, the processing recipe ID, and any material-related quality measurements such as any physical measurements, for example film thickness, film resistivity, critical dimension, defect data, and any electrical measurements, for example transistor threshold voltage, transistor saturation current (IDSAT), or any equivalent material-related quality measurements.

The tool-related data from tools 604-610 may be collected using an appropriate 110 module or I/O modules and may include, for example, the date/time information, the tool ID, the processing recipe ID, subsystems and tool component historical data, and any other process-related measurements, for example pressure, temperature, gas flows

In one or more embodiments, the date/time, tool ID and optionally recipe may be employed as common attributes or correlation keys to align or correlate, using appropriate logic (which may be implemented via dedicated logic or as software executed in a programmable logic/processor for example) the tool-related data with the material-related data for example, tool-related parameter values with metrology measurement values on specific materials (i.e., wafers), thereby permitting a computer-implemented algorithm to correctly correlate and perform the automated analysis on the combined material-related data and tool-related data.

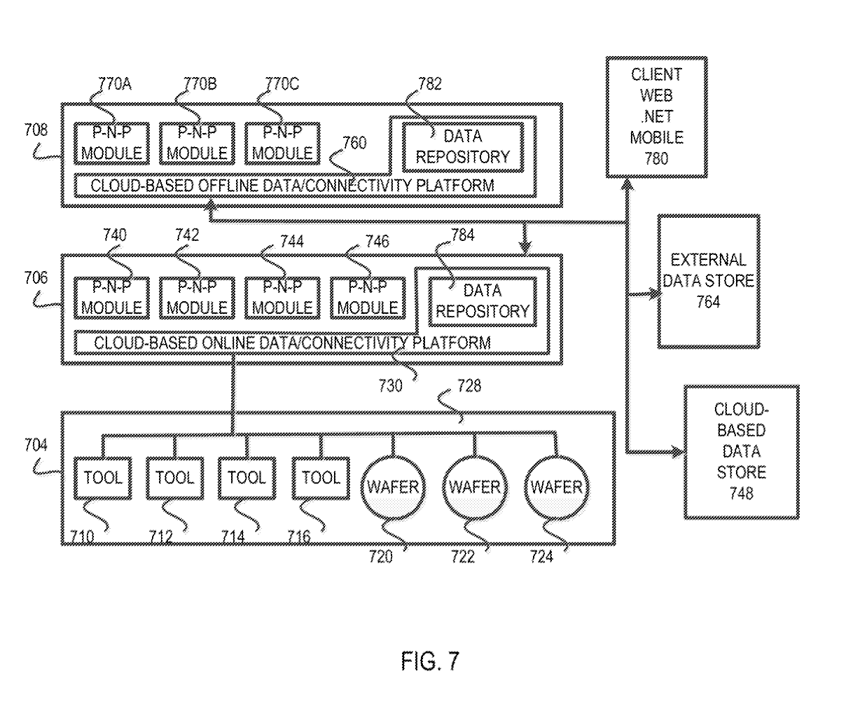

FIG. 7 shows, in accordance with an embodiment of the invention, a more detailed view of a cloud-based YiEES system. With respect to FIG. 7, the cloud-based YiEES system includes 3 conceptual layers; data layer 704, online cloud-based control/analysis layer 706, and offline cloud-based analysis layer 708. Since the implementation of FIG. 7 employs cloud-based computing approach, layers 706 and 708 may be offered as services.

Data layer 704 represents layer wherein the tools (710-716) and/or wafers (720-724) conceptually reside and from which tool-related and material-related data may be obtained via appropriate I/O modules. In general terms, the tool-related data may be thought of as cause data for the automated analysis, and material-related data may be thought of as effect data for the automated analysis. As can be seen in FIG. 7, both the cause and effect data are present in a single platform, collected and sent to cloud-based online/analysis layer 706 via data channel 728.

Cloud-based online control/analysis layer 706 represents the cloud-based, layer or service that contains the plug-and-play modules for performing automated control, optimization, analysis, and/or prediction based on the integrated tool-related and material-related data collected from data layer 704. To facilitate plug-and-play modules for online control/analysis, a cloud-based data/connectivity platform 730 serves to interface with data channel 728 to obtain tool-related and material-related data from data layer 704 as well as to present a standard interface to communicate with the plug-and-play modules. For example, cloud-based data/connectivity platform 730 may implement APIs (application programming interfaces) with pre-defined connectivity and communication options for the plug-and-play modules.

Plug-and-play modules 740, 742, 744, 746 represent 4 plug-and-play modules to, for example, perform the automated control (SPC, MPC, APC), tool profiling, process profiling, tool optimization, processing optimization, modeling building, dynamic model update and modification, analysis, and/or prediction using the integrated tool-related and material-related data collected from data layer 704. The plug-and-play modules may be implemented via dedicated logic or as software executed in a programmable logic/processor, for example. Each of plug-and-play modules 740, 742, 744, 746 may be configured as needed depending on the specifics of a process, the needs of a particular customer, etc. Sharing the same platform allow each module to feed and receive useful information from others.

For example, if the cloud-based YiEES system, for example the offline analysis part (be discussed later herein), found a strong correlation between a specific tool-related parameter (such as etch time with a material-related parameter of interest (e.g., leakage current of transistors), this knowledge is saved in the knowledge base of data repository 764 as part of the tool profile and/or used to create or update existing models related to this tool/or process in process control, prediction, and/or process optimization. A plug-and-play module 740 that is coupled with cloud-based data/connectivity layer 730 may monitor etch time values (e.g., with high/low limit) and use the result of that monitoring to control the tool and/or optimize the tool and/or process in order to ensure the process is controlled/optimized to satisfy a particular leakage current specification. The new knowledge can also be used by existing module for new model creation or existing model updates. This is an example of a plug-and-play tool that can be configured and updated quickly by the tool user and plugged into cloud-based data/connectivity platform 730 to receive integrated tool-related and material-related data (e.g., both cause and effect data) and to provide additional control/optimization capability to satisfy a customer-specific material-related parameter of interest.

As another example, if the cloud-based YiEES system, for example the off-line analysis part (to be discussed later herein), found as strong correlation between a group of specific tool-related parameters (such as etch time and chamber pressure and RF power to the electrodes) with a material-related parameter of interest (e.g., critical dimension of a via), this knowledge is saved in the knowledge base as part of the tool profile and/or used to create or update existing models related to this tool/or process in process control, prediction, and/or process optimization. A plug-and-play module 742 that is coupled with cloud-based data/connectivity layer 730 may monitor values associated with this group of specific tool-related parameters (which may be conceptualized as a virtual parameter that is a composite of individual tool-related parameters) and use the result of that monitoring to control the tool and/or optimize the tool and/or process in order to ensure the process is controlled/optimized to satisfy a particular via CD (critical dimension) specification. The new knowledge can also be used by existing module for new model creation or existing model optimization. This is an example of another plug-and-play tool that can be configured and updated quickly by the tool user and plugged into cloud-based data/connectivity platform 730 to receive integrated tool-related and material-related data (e.g., both cause and effect data) and to provide additional control/optimization capability to satisfy a customer-specific material-related parameter of interest or a group of material-related parameters of interest.

As another example, if the cloud-based YiEES system, for example the off-line analysis part (to be discussed later herein), found a strong correlation between specific tool-related (e.g., temperature) parameter and/or material-related (e.g., leakage current) parameter with yield, this knowledge is saved in the knowledge base as part of the tool profile and/or used to create or update existing models related to this tool/or process in process control, prediction, and/or process optimization. Plug-and-play module 744 or plug-and-play module 746 that is coupled with cloud-based data/connectivity layer 730 in order to monitor these specific tool-related parameter (e.g., temperature) and material-related parameter (e.g., leakage current) may predict the yield with high data granularity. The new knowledge can also be used by existing module for new model creation or existing model optimization. Each of modules 744 or 746 is an example of a plug-and-play tool that can be configured and updated quickly by the tool user and plugged into cloud-based data/connectivity platform 730 to receive integrated tool-related and material-related data (e.g., both cause and effect data) and to provide analysis and/or prediction capability to satisfy a customer-specific yield requirement.

Cloud-based data store 748 may be implemented by the aforementioned HDFS (Hadoop Distributed File System or any type of data source or a combination thereof. Cloud-based data/connectivity platform 730 is provided with interfaces to interact with each of these data sources to pull the necessary data for the online analysis tasks. Cloud-based online integrated tool-related and material-related data store 748 represents a data store that stores at least sufficient data to facilitate the online control/analysis needs of modules 740-746. In an embodiment, the data in clouded-based data store 748 represents or includes a portion of the data residing in external data repository 764, which portion is copied onto cloud-based data store 748 for use by the on-line analysis layer/service 706. Since data store 748 conceptually represents the data store serving the online control/analysis needs, archive tool-related and material-related data from past processes may be optionally stored in data store 748 (but not required in data store 748 in one or more embodiments).

Cloud-based offline analysis layer 708 represents the cloud-based layer or service that facilitates off-line data extraction, analysis, viewing and/or configuration by the user. In contrast to cloud-based online control/analysis layer 706, cloud-based offline analysis layer 708 relies more heavily on archival data as well as analysis result data from cloud-based online control/analysis layer 706 (instead of or in addition to the data currently collected from tools 710-716 and wafers 720-724) and/or knowledge base and facilitates interactive user analysis/viewing/configuration.

A cloud-based data/connectivity platform 760 serves to interface with cloud-based online control/analysis layer 706 to obtain the data currently collected from tools 710-716 and wafers 720-724, from the analysis result data from the plug-and-play modules of cloud-based online control/analysis layer 706, from the data stored in data store 748, from a knowledge base from the archival data store (which stores tool-related and material-related data), and/or from the legacy data stores (which may represent, for example, third-party or customer databases that may have tool-related or material-related or analysis results that may be of interest to the off-line analysis).

Cloud-based data/connectivity platform 760 also presents an interface to communicate with the plug-and-play offline modules. For example, cloud-based data/connectivity platform 760 may implement APIs (application programming interfaces) with pre-defined connectivity and communication options for the offline plug-and-play extraction module or offline plug-and-play configuration module or offline plug-and-play analysis module or online plug-and-play viewing module. The off-line plug-and-play modules may be implemented via dedicated logic or as software executed in a programmable logic/processor or software executed using cloud-based computing services, for example. These offline extraction, analysis, configuration and/or viewing modules may be quickly configured as needed by the customer and plugged into cloud-based data/connectivity platform 750 to receive current and/or archival integrated tool-related and material-related data (e.g., both cause and effect data) as well as current and/or archival online analysis results and/or data from third party databases in order to service a specific extraction, analysis, configuration and/or viewing need.

Interaction facility 780 conceptually facilitates accessing to the cloud-based YiEES by any number/type of user-interface devices, including for example web clients (which may include browsers implemented on smart phones, tablets, dedicated control devices, laptop computers, desktop computers, etc.), .NET client, and/or similar cloud-computing interaction technologies. Access may also be provided through plug-and-play modules 770A, 777B, 770C in the manner discussed in connection with corresponding plug-and-play modules in FIG. 3.

External data repository 764 may be implemented using any or a combination of data store technologies including for example, HDFS, relational databases, structured databases, etc. Data may be copied onto local repositories 782 and 784 for use as needed by respective clouded-based offline control/analysis layer 708 and cloud-based online analysis layer 706

In one or more embodiments, part of the YiEES functionality may be implemented using cloud-based computing, and part of the YiEES functionality may be implemented using another technology, such as client-server. The cloud-based services may extract data from cloud-based stores/platform such as HDFS or from traditional databases using third-party tools. The client-server executables may extract data from traditional databases or from cloud-based data stores using third-party tools. Allowing different technologies to implement different technologies enables the user to maximize his investment in existing IT infrastructure while updating only the portion that needs the cloud-based computing capability, for example. For example, some functions are only available on client-server platforms and those functions may continue to operate on the client-server platform. Other functions that require handling a large amount of data and/or a large variety of data and/or require more flexible scalability of resources may be updated to employ cloud-computing technology, for example.

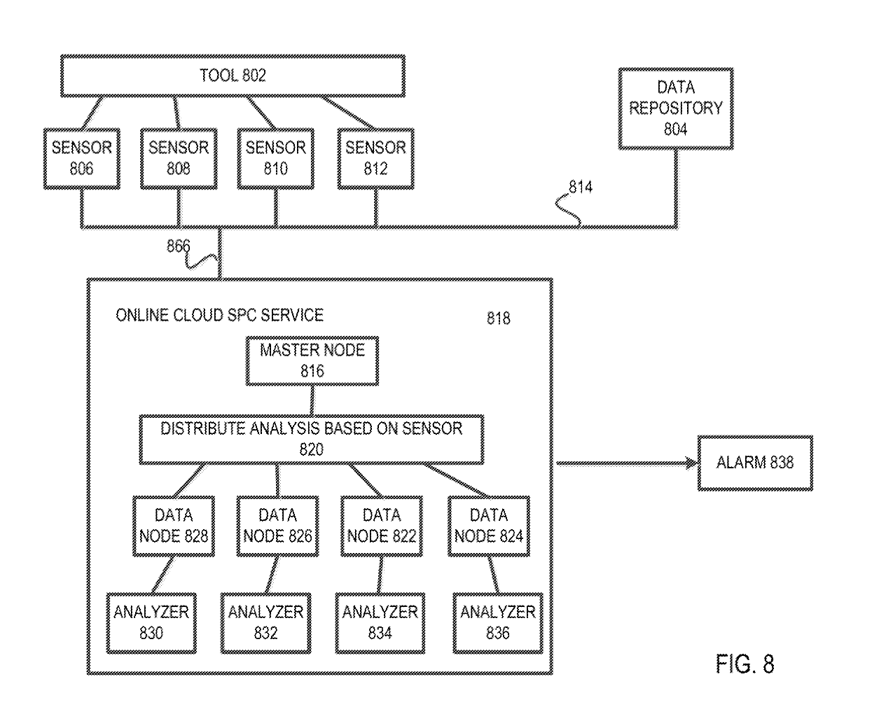

FIG. 8 shows an example cloud-based statistical process control that has been implemented as a service using the cloud-based (i.e., cloud computing) approach. SPC service 802 receives tool trace data from sensors (such as temperature, pressure, voltage, etc.) and apply rules to implement specific action such as for example sounding an alarm if an upper or lower limit of a given parameter is reached; shut down the process if a certain limit of a certain parameter is reached; alert an administrator if a certain limit of is certain parameter is reached; modify the process recipe in a certain way if a certain limit of a parameter is reached, etc.).

In FIG. 8, 802 represents the tool (e.g., the processing equipment employed to process wafers). Sensors 806-812 represent the sensors that obtain the tool data as processing takes places and sends (866) the data to cloud-based online SPC service 818 and/or data repository 804. Data repository 804 may represent purely distributed, cloud-based data (such as that implemented using HDFS) or may represent one or more relational database or a combination of HDFS and relational databases.

Cloud-based online SPC service 818 receives data from sensors 806-812 and interacts with data repository 804 to access data needed for analysis (such as for example domain knowledge, historical data, expert knowledge, etc.). In one cloud-based computing approach, a master node 816 serves as a master coordinator to obtain data from sensors 806-812 and/or data repository 804) on behalf of data nodes 822, 824, 826, and 828 and to distribute the data to the appropriate data nodes (820) and to receive the data analysis result (830, 832, 834, and 836) from the data nodes.

For example if data node 822 is employed to analyze pressure data for SPC purposes, master node 816 would provide pressure data from the pressure sensor 806, along with any relevant data from data repository 804, to data node 822 to enable data node 822 to perform the analysis on the pressure data. The analysis result (834) is then provided to master node 816 for action (such as alarm 838).

As another example if data nodes 826 and 828 are employed to analyze temperature data for SPC purposes, master node 816 would provide temperature data from the temperature sensor 808, along with any relevant data from data repository 804, to data nodes 826 and 828 to enable data nodes 826 and 828 to perform the analysis on the temperature data. The analysis result (830 and 832) from the temperature trace data is then provided to master node 816 for action.

Although two data nodes are mentioned in the above example, any number of data nodes may be employed (per scalability needs) to analyze a particular trace. Taking advantage of the scalability of cloud based computing, it is possible to handle complex analysis tasks involving a large volume of data and/or different types of data without requiring the use of powerful servers (which would be expensive to maintain/provision) and without requiring the dedication of expensive and powerful hardware for peak demands. Instead, computing resources may be virtually scaled by adding computing capability as needed.

In one or more embodiments, the same trace data (e.g., bias voltage) may be provided to multiple data nodes to ensure there is redundancy in data storage. In this manner, if a data node fails during analysis, another data node is already provided with the bias voltage data and is already performing the same analysis as the data node that failed. Master node 816 would seamlessly obtain the analysis results from the redundant node, thus ensuring that analysis is uninterrupted.

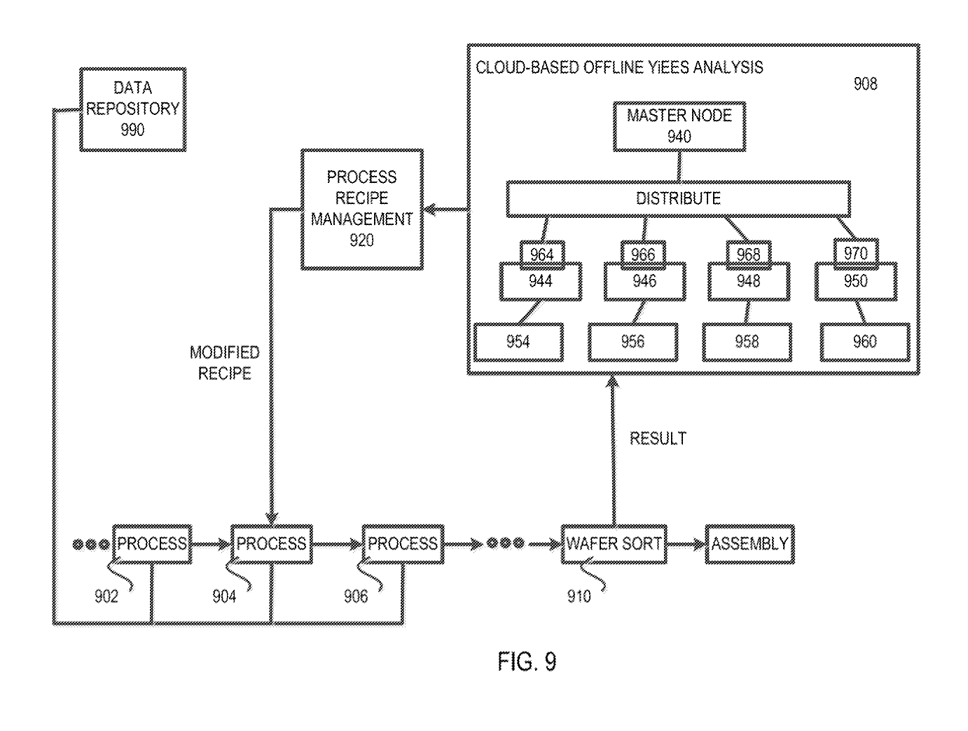

FIG. 9 shows the implementation of an example cloud-based online control/optimization module that is analogous to the plug-and-play modules discussed in connection with cloud-based online control/analysis layer 706 of FIG. 7. In FIG. 9, the tool-related data from processes 902, 904, and 906 (which may represent respectively metal etch, polysilicon etch, and CMP, for example) may be collected and inputted into a cloud-based control/optimization module 908. Once processing is done, wafer sort process 910 may perform electrical parameter measurements, device yield measurements, and/or other measurements and input the material-related data into cloud-based control/optimization module 908.

Cloud-based control/optimization module 908, which represents a plug-and-play module, may automatically analyze the tool-related data and the material-related data and determine that there is a correlation between chamber pressure during the polysilicon etch step (a tool-related data parameter) and the leakage current of a gate (a material-related data parameter). This analysis result may be employed to modify a recipe setting, which is sent to process recipe management block 920 to create a modified recipe to perform tool control or to optimize tool control for tool 904. Note that the presence of highly granular tool-related, data and material-related data permit root cause analysis that narrows down to one or more specific parameters in a specific tool, which facilitates highly accurate recipe modification. Accordingly, the availability of both tool-related data and material-related data and the ease of configuring/implementing, a plug-and-play module to perform the analysis on the integrated tool-related data and material-related data greatly simplify the automated analysis and control task. In addition, based on the above analysis, a prediction model can be built or optimized and its results can be passed to other plug and play modules (for example 906) as inputs. This is also an example of feed-forward and feed-backward capability of the plug and play module in the system.

Automated analysis of effect (e.g., yield result based on integrated tool-related and material-related data) and/or prediction (e.g., predicted yield result based on integrated tool-related and material-related data) may be improved using a knowledge base. In one or more embodiments, human experts may input root-cause analysis or prediction knowledge into a knowledge base to facilitate analysis and/or prediction. The human expert may, for example, indicate a relationship between saturation current measurements for a transistor gate and polysilicon critical dimension (C/D).

Previously obtained root-cause analysis such as one which pinpoints tool-related parameters correlating to yield-related problems) and previously obtained prediction models from the cloud-based YiEES system (such as from one or more of plug-and-play modules 740-746 of cloud-based online control/analysis layer 706 of FIG. 7 or one or more of plug-and-play modules of cloud-based online analysis layer 708) may also be input into the knowledge base. For example, prior analysis may correlate a particular etch pattern on the wafer with a particular pressure setting on a particular tool. This correlation may also be stored into the knowledge base.

The root-cause analysis and/or prediction knowledge from the human expert and/or from prior analysis/prediction module outputs may then be applied against the integrated tool-related data and material-related data to perform root cause analysis or to build new prediction models. The combination of a knowledge base, tool-related data, and material-related data in a single platform renders the automated analysis more accurate and less time-consuming.

In one or more embodiments, multiple potential root causes or prediction models may be automatically provided by the knowledge base, along with a ranking of probability, in order to give the tool operator multiple options to investigate. Furthermore, the root-cause analysis and/or prediction models obtained using the assistance of the knowledge base may be stored back into the knowledge base to improve future root-cause analysis and/or prediction. To ensure the accuracy of the generated root-cause analysis or prediction models, analysis and model validation (via techniques like cross validation) may be performed periodically if desired.

Expert or domain knowledge may also be employed to automatically combine analysis results and influence the ranking (via changing the weight assigned to the individual results, for example) of the analysis result candidates. For example, the set of candidate analysis results (obtained with statistical method alone or with or without knowledge base assistance) may be automatically combined, so that the results are significant in both statistical and practical senses.

As an example, the expert may input, as a rule into the analysis engine, that yield loss around the edge is likely associated with etch problems and more specifically with high bias power during the main etch step. Accordingly, the set of analysis result candidates that may have been obtained using a purely statistical approach or a combination of a statistical approach and other knowledge base rules may be influenced such that those candidates associated with etch problems and more specifically those analysis results associated with high bias power during main etch step would be emphasized (and other candidates de-emphasized). Note that this type of root cause analysis granularity is possible only with the provision of integrated tool-related data and material-related data in a single platform, in accordance with one or more embodiments of the invention.

Cloud-based control/optimization module 908 is implemented using the cloud-based approach and involves, in an embodiment, the master node-data node concept discussed earlier in connection with FIG. 8. In the specific example of FIG. 9, master node 940 distributes the data required for analysis based on process step (942). For example, the data (or a portion thereof) from data repository 990 is distributed as needed by master node 940 to local data stores 964, 966, 968, and 970 for use by respective data nodes 944, 946, 948, 950. The analysis is performed by one or more of data nodes 944, 946, 948, 950 as needed (which execute analyze modules 954, 956, 958, and 960 respectively). The analysis result is returned to master node 940 for control/optimization purposes.

As mentioned in connection with FIG. 5, analysis may, alternatively or additionally, be made more efficient/accurate by first performing automated clustering/classification of wafers, and then applying different automated analyses to different groups of wafers. Using the cloud-based approach, different data nodes or different groups of data nodes may be employed to perform of different analysis that utilize both tool-related and material-related data. The result is a highly efficient root caused analysis that utilizes the advantages of the YiEES system and the power of cloud-based computing.

As can be appreciated from the foregoing, by implementing the inventive YiEES system using the cloud-based computing approach, the inventive YiEES system can handle even larger volume of data and/or data collected at higher frequency and/or different variety of data. This is mainly due to the scalability and ease of provisioning of the cloud-based computing approach. Software installation and/or maintenance is simplified as software maintenance and installation is handled centrally in accordance with cloud-computing methodologies and an applications/data are accessed as services through the web interface on an as-needed basis. By employing redundant data nodes to handle the analysis tasks, the YiEES system may be made even more robust than that implemented by traditional technologies such as client-server technology.

While this invention has been described in terms of several preferred embodiments, there are alterations, permutations, and equivalents, which fill within the scope of this invention. For example, although the examples herein refer to wafers as examples of materials to be processed, it should be understood that one or more embodiments of the invention apply to any material processing, tool and/or any material. In fact, one or more embodiments of the invention apply to the manufacture of any article of manufacture in which tool information as well as material information is collected and analyzed by the single platform. If the term “set” is employed herein, such term is intended to have its commonly understood mathematical meaning to cover zero, one, or more than one member. The invention should be understood to also encompass these alterations, permutations, and equivalents. It should also be noted that there are many alternative ways of implementing the methods and apparatuses of the present invention. Although various examples are provided herein, it is intended that those examples be illustrative and not limiting with respect to the invention.

What is claimed is:

1. A cloud-based integrated yield/equipment data processing system for collecting and analyzing integrated tool related data and material-related data pertaining to at least one material processing tool and at least one material, comprising:
at least a first module for collecting said tool-related data pertaining to said at least one material processing tool:
at least a second module for collecting said material-related data pertaining to said at least one material:
first logic for correlating said tool-related data with said material-related data, thereby obtaining correlated tool-related data and material-related data and second logic for analyzing said correlated tool-related data and material-related data to perform at least one of root-cause analysis, prediction model building and tool control/optimization, wherein at least one of said first logic, and said second logic is implemented using a cloud computing approach.

2. The cloud-based integrated yield/equipment data processing system of claim 1 further including third logic for updating a knowledge base with at least one of said root-cause analysis and a cause-effect relationship between said tool-related data and said material-related data.

3. The cloud-based integrated yield/equipment data processing system of claim 2 wherein at least one of said correlating and said analyzing also utilizes said knowledge base.

4. cloud-based integrated yield/equipment data processing system of claim 2 wherein said knowledge base includes at least on of tool profiles, process profiles, and cause-effect relationships between certain previously acquired tool-related data and certain previously acquired material-related data.

5. The cloud-based integrated yield/equipment data processing system of claim 1 further including at least one offline analysis module that performs at least one of data extraction, analysis, viewing and configuration on archival data, the archival data including both prior recorded tool-related data and prior-recorded material-related data.

6. The cloud-based integrated yield/equipment data processing system of claim 1 wherein said second logic includes at least a data/connectivity platform and at least one analysis module, wherein said data/connectivity platform facilitates data connectivity for obtaining said tool-related data and said material-related data, said at least one analysis module performing said at least one of root-cause analysis, prediction model building and tool control/optimization utilizing said tool-related data and said material-related data.

7. The cloud-based integrated yield/equipment data processing system of claim 6 wherein said at least one analysis module performs said root-cause analysis.

8. The cloud-based integrated yield/equipment data processing system of claim 7 wherein said root-cause analysis is performed using a correlation result that is pre-stored in a knowledge database.

9. The cloud-based integrated yield/equipment data processing system of claim 8 wherein said correlation result is obtained by prior off-line analysis on a different set of said tool-related data and said material-related data.

10. The cloud-based integrated yield/equipment data processing system of claim 6 wherein said at least one analysis module represents a root cause analysis module, said root cause analysis module producing multiple probable root causes ranked by a probability ranking.

11. The cloud-based integrated yield/equipment data processing system of claim 10 wherein said probability ranking is produced using at least one of expert domain knowledge and historical knowledge learning that has been pre-stored in a database.

12. The cloud-based integrated yield/equipment data processing system of claim 6 wherein said at least one analysis module represents a root cause analysis module, said root cause analysis module performing at least one of clustering and classification on a set of materials to facilitate analysis using different statistical methods.

13. The cloud-based integrated yield/equipment data processing system of claim 6 wherein said at least one analysis module performs said tool control/optimization.

14. The cloud-based integrated yield/equipment data processing system of claim 13 wherein said tool control/optimization is performed using a correlation result that is pre-stored in a knowledge database.

15. The cloud-based integrated yield/equipment data processing system of claim 14 wherein said correlation result is obtained by prior off-line analysis on a different set of said tool-related data and said material-related data.

16. The cloud-based integrated yield/equipment data processing system of claim 6 wherein said at least one analysis module performs said prediction model building.

17. The cloud-based integrated yield/equipment data processing system of claim 16 wherein said prediction model building is performed using a correlation result that is pre-stored in a knowledge database.

18. The cloud-based integrated yield/equipment data processing system of claim 17 wherein said correlation result is obtained by prior off-line analysis on a different set of said tool-related data and said material-related data.

19. An cloud-based integrated yield/equipment data processing system for collecting and analyzing integrated tool-related data and material-related data pertaining to at least one material processing tool and at least one material, comprising:
means for collecting said tool-related data pertaining to said at least one material processing tool and said material-related data pertaining to said at least one material;
means for correlating said tool-related data with said material-related data, thereby obtaining correlated tool-related data and material-related data; and
means for analyzing said correlated tool-related data and material-related data to perform at least one of root-cause analysis, prediction model building and tool control/optimization, wherein at least one of means for correlating and said means for collecting is implemented using a cloud computing approach.

20. The cloud-based integrated yield/equipment data processing system of claim 19 wherein said means for correlating, correlates said tool-related data with said material-related data using at least date/time and tool ID.
